(19) United States
(12) Patent Application Publication
(10) Pub. No.: US 2016/0014885 A1
(43) Pub. Date: Jan. 14, 2016

(54) NETWORK DEVICE, SYSTEM AND METHOD HAVING A ROTATED CHIP FLOORPLAN

(71) Applicant: XPLIANT, Inc., San Jose, CA (US)

(72) Inventors: Amir H. Motamedi, Sunnyvale, CA (US); Nikhil Jayakumar, Sunnyvale, CA (US); Bhagavathi R. Mula, San Jose, CA (US); Vivek Trivedi, Fremont, CA (US); Vasant K. Palisetti, Santa Clara, CA (US); Daman Ahluwalia, Los Gatos, CA (US)

(21) Appl. No.: 14/331,099

(22) Filed: Jul. 14, 2014

(51) Int. Cl. H05K 1/02; G02B 6/26; H05K 1/18; H05K 3/30

(52) U.S. Cl. CPC H05K 1/0216; H05K 3/30; G02B 6/26; H05K 1/18; H05K 1/0203

(57) ABSTRACT

An information processing system including a support structure supporting a plurality of blade boards configured to detachably couple to an electronic interface of the structure. The blade boards each include a printed circuit board having a front board edge, one or more optical interface modules positioned on the front edge of the circuit board and a processing chip coupled to the circuit board and having a plurality of pin outs that are each electrically coupled to at least one of the optical interface modules via one or more traces on the circuit board. Further, the sides of the processing chip are non-parallel with the front board edge of the printed circuit board. As a result, the board is able to simultaneously reduce trace length and increase cooling efficiency of the system.

### FIELD OF THE INVENTION

The invention relates to the field of network devices. In particular, the invention relates to chip placement and design for network devices, systems and methods.

### BACKGROUND OF THE INVENTION

During the floor planning for a network element (e.g. blade board), the question of positioning the device (chip) on the printed circuit board of the network element is the one of the most important issues which the hardware designer or the layout engineer faces. Two classical problems during such a floor planning stage exist. First, the distance of the chip from other components affects the lengths of traces between the chip and the other components of the network element. Specifically, long trace lengths on high speed links can have high frequency losses which limits the reach of the signals and thus the dimensions and performance of the network element. Second, if the chip is placed too close to certain other components cooling of the chip and/or the other components becomes more difficult. Specifically, the proximity of the chip and the other components can cause excessive temperatures, which would violate the thermal specification of the chip, the other components, or both. As a result, the floor planning of the network element has generally required a sacrifice in either trace length or cooling efficiency.

### SUMMARY OF THE INVENTION

Embodiments of the invention are directed to a information processing system, device and method wherein the sides of the processing chip are non-parallel with a line of a plurality of optical interface modules and/or other interface modules with which they are electrically coupled. As a result, the length of the electrically coupling traces between the chip and the modules is reduced thereby improving signal quality. Additionally, the chip is able to be oriented such that a hotspot of the chip is positioned along a leading edge or edges of the chip that are nearest the line of modules and the cooling air (which is generally from front to back). As a result, the chip is more efficiently cooled by receiving the cooler air at the leading edge and less heat is dissipated between the chip and the modules as a majority of the leading edges of the chip are a further distance away from the front edge of the printed circuit board.

A first aspect is directed to an information processing system. The information processing system comprises a support structure having an electronic interface and a plurality of blade boards each configured to detachably couple to the electronic interface, wherein each of the blade boards comprise a printed circuit board having a front board edge, one or more optical interface modules positioned on the front edge of the circuit board and a processing chip coupled to the circuit board and having a plurality of pin outs that are each electrically coupled to at least one of the optical interface modules via one or more traces on the circuit board, wherein the sides of the processing chip are non-parallel with the front board edge of the printed circuit board. In some embodiments, the sides of the processing chip are angled 45 degrees with respect to the front board edge. In some embodiments, the perimeter of the processing chip comprises four corners and four sides in between the corners. In some embodiments, the processing chip comprises ternary content-addressable memory located along one of the two sides closest to the optical interface modules. In some embodiments, the sides of the processing chip are angled with respect to the front board edge such that the length of the traces between the pinouts and the optical interface modules is minimized. In some embodiments, the support structure comprises a cooling element that forces air to move from the front board edge of the printed circuit board of each of the blade boards to a back board edge of the printed circuit board that is opposite the front board edge.

A second aspect is directed to a blade board for use in a information processing system. The blade board comprises a printed circuit board having a front board edge, one or more optical interface modules positioned on the front edge of the circuit board and a processing chip coupled to the circuit board and having a plurality of pin outs that are each electrically coupled to at least one of the optical interface modules via one or more traces on the circuit board, wherein the sides of the processing chip are non-parallel with the front board edge of the printed circuit board. In some embodiments, the sides of the processing chip are angled 45 degrees with respect to the front board edge. In some embodiments, the perimeter of the processing chip comprises four corners and four sides in between the corners. In some embodiments, the processing chip comprises ternary content-addressable memory located along one of the two sides closest to the optical interface modules. In some embodiments, the sides of the processing chip are angled with respect to the front board edge such that the length of the traces between the pinouts and the optical interface modules is minimized.

A third aspect is directed to a method of providing a blade board for use in an information processing system. The method comprises providing a blade board having a printed circuit board including a front board edge and one or more optical interface modules positioned on the front edge of the circuit board and coupling a processing chip to the printed circuit board such that the sides of the processing chip are non-parallel with the front board edge of the printed circuit board, wherein the processing chip comprises a plurality of pin outs that are each electrically coupled to at least one of the optical interface modules via one or more traces on the circuit board. In some embodiments, the sides of the processing chip are angled 45 degrees with respect to the front board edge. In some embodiments, the perimeter of the processing chip comprises four corners and four sides in between the corners. In some embodiments, the processing chip comprises ternary content-addressable memory located along one of the two sides closest to the optical interface modules. In some embodiments, the sides of the processing chip are angled with respect to the front board edge such that the length of the traces between the pinouts and the optical interface modules is minimized. In some embodiments, the method further comprises detachably electrically coupling the blade board to an electronic interface of a support structure. In some embodiments, the method further comprises moving air from the front board edge of the printed circuit board of the blade board to a back board edge of the printed circuit board that is opposite the front board edge with a cooling element of the support structure.

### BRIEF DESCRIPTION OF THE DRAWINGS

FIG. 1 illustrates a block diagram of an information processing system according to some embodiments.

FIG. 2A illustrates a top view of one of the information processing devices according to some embodiments.

FIG. 2B illustrates a top view of one of the information processing devices having a hotspot H according to some embodiments.

FIG. 3 illustrates a flow chart of a method of manufacturing an information processing device for use in an information processing system according to some embodiments.

### DETAILED DESCRIPTION OF THE PRESENT INVENTION

Embodiments of the information processing system, device and method comprise a support structure supporting a plurality of blade boards configured to detachably couple to an electronic interface of the structure. The blade boards each include a printed circuit board having a front board edge, one or more optical interface modules positioned on the front edge of the circuit board and a processing chip coupled to the circuit board and having a plurality of pin outs that are each electrically coupled to at least one of the optical interface modules via one or more traces on the circuit board. Further, the sides of the processing chip are non-parallel with the front board edge of the printed circuit board. As a result, the board is able to simultaneously reduce trace length and increase cooling efficiency of the system.

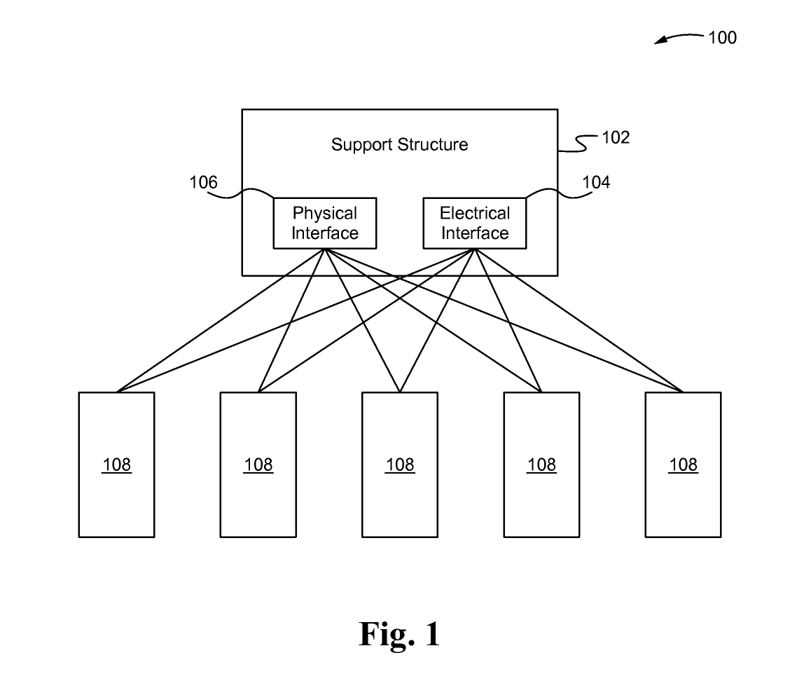

FIG. 1 illustrates a block diagram of an information processing system 100 according to some embodiments. As shown in FIG. 1, the information processing system 100 comprises a support structure 102 having an electrical interface 104 and a physical interface 106 electrically and physically coupled with one or more information processing devices 108. In particular, the information processing devices 108 are able to be removably coupled to the support structure 102 physically via the physical interface 106 and electrically via the electrical interface 104 such that information processing devices 108 are able to be added, removed or swapped as desired. Additionally, the information processing system 100 is able to comprise one or more cooling elements (e.g. cooling fans, heat sinks, vacuums), one or more power sources and/or other networking, interconnect and management elements as are well known in the art. For example, a vacuum as able to be used to suction air and/or a fan is able to blow air over hotspots of the system 100 (e.g. information processing devices 108) in order to produce an airflow in a desired direction with respect to the system 100.

In some embodiments, the information processing system 100 is a data center wherein the physical interface 106 is a rack or chassis with one or more housing modules/compartments for receiving, supporting and physically coupling to the processing devices 108, and the electrical interface 104 is a top of rack (ToR) switch and one or more coupling cables for electrically coupling each of the processing devices 108 to the ToR switch, a coupled network (e.g. the Internet) and/or each other. In such embodiments, the processing devices 108 are able to comprise blades, blade servers or blade boards. For example, the blade servers 108 are able to be “stripped down” servers with a modular design optimized to minimize the use of physical space and energy. Alternatively, the processing devices 108 are able to comprise one or more other types of processing devices such as servers or other devices well known in the art. Alternatively or in addition, the electrical interface 104 is able to comprise a backplane for connecting the processing devices 108 to power and other data transfer devices.

In some embodiments, the information processing system 100 is a backplane, midplane or butterfly system wherein the physical interface 106 and the electrical interface 104 are able to be combined as a backplane, midplane or butterfly back board that both physically and electrically couple and/or provide power to each of the processing devices 108. For example, the backplane, midplane and/or butterfly are able to each comprise a group of electrical connectors in parallel with each other, so that each pin of each connector is linked to the same relative pin of all the other connectors forming a computer bus. Alternatively or in addition, the physical interface 106 is able to comprise a device chassis or housing for supporting the backplane, midplane and/or butterfly back board. Additionally, the electrical interface 104 is able to comprise switch fabric including one or more switches (e.g. crossbar switches) for coupling to the physical interface 106 (e.g. back plane) and thereby coupling the processing devices 108 together. In such embodiments, the processing devices 108 are able to comprise card/line cards configured to electrically and physically couple to the physical/electrical interfaces 104, 106 (e.g. back plane). Alternatively, the processing devices 108 are able to comprise one or more other types of processing devices such as servers or other devices well known in the art.

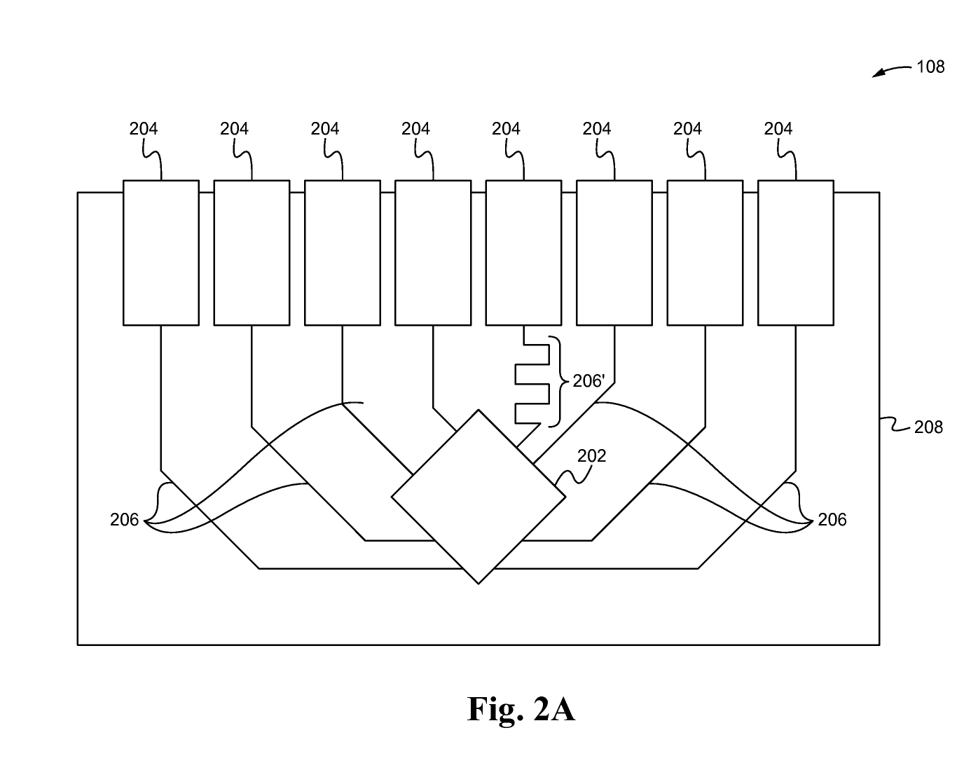

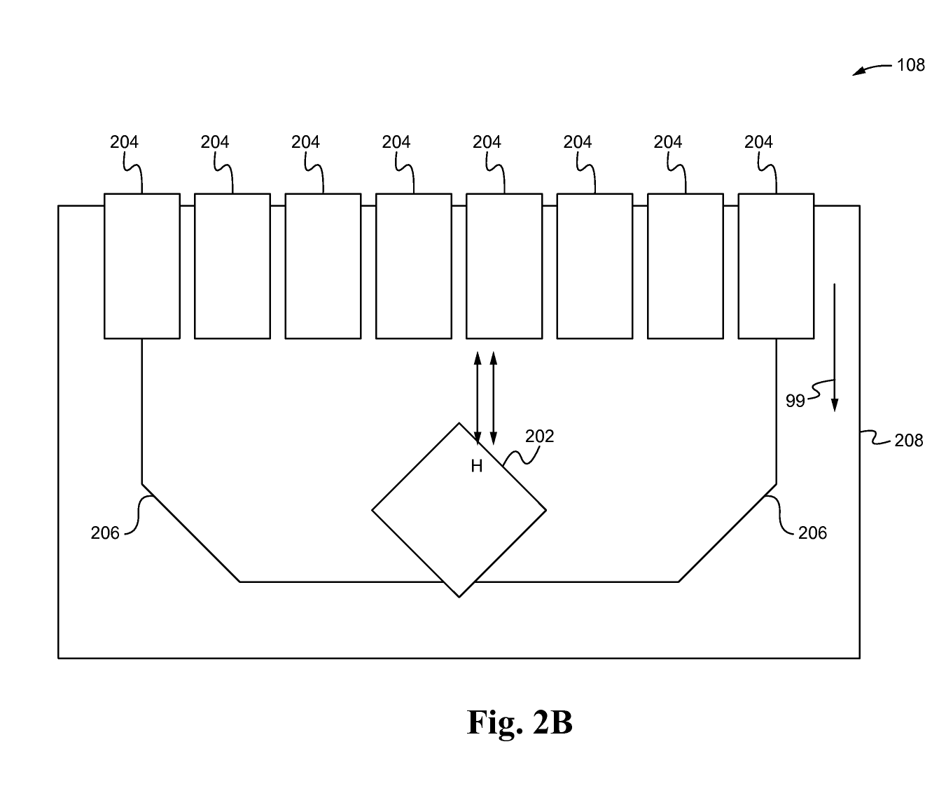

FIG. 2A illustrates a top view of one of the information processing devices 108 according to some embodiments. As shown in FIG. 2A, the processing device 108 comprises a central processing unit (cpu) or chip 202 electrically coupled with one or more optical interface modules 204 via one or more traces 206. The chip 202, modules 204 and traces 206 are all supported by a rigid substrate 208 such as a printed circuit board. Although as shown in FIG. 2, the processing device 108 comprises a single chip 202 coupled with eight optical interface modules 204, additional chips and/or more or less modules 204 are contemplated. In some embodiments, the processing device 108 is able to further comprise one or more heat sinks (not shown) coupled with the modules 204 and/or the chip 202 for removing heat from the modules 204 and/or the chip 202. Additionally, it is understood that the processing device 108 is able to comprise more or less components well known in the art which have been omitted here for the sake of brevity.

As shown in FIG. 2A, the chip 202 is rotated or angled with respect to the substrate 208 and/or the optical modules 204 such that the edges or sides of the chip 202 are non-parallel with the edges or sides of the substrate 208 and/or the optical modules 204 (or a line that intersects the center of two or more of the optical modules 204). For example, in some embodiments, the sides of the chip 202 form a 45 degree angle with one or more of the sides of the substrate 208 and/or optical modules 204. Alternatively, the chip 202 is able to be rotated such that the sides of the chip 202 form any non-parallel angle with one or more of the sides of the substrate 208, of other components on the substrate 208 (e.g. memory modules) and/or of the optical modules 204. In some embodiments, the chip 202 is rotated such that the pin outs (e.g. power) electrically coupled with the components are located on one of the sides closest to the substrate 208 and/or the optical modules 204. As a result of this rotation of the chip 202, the processing device 108 is able to provide the advantage of reducing the excessively long length and thereby the signal integrity loss produced by the traces 206 which couple the pin outs of the chip 202 to the optical modules 204. At the same time, by angling the chip 202 there is the added benefit that the cross heating between the chip 202 and the optical modules 204 is limited due to the distancing portions of the chip 202 from the modules 204.

Additionally, in some embodiments one or more of the shortest traces 206′ coupled between the pin outs and optical modules 204 closest to each other are able to form serpentine or other non-linear paths in order to add to the length of the traces 206′ such that a minimum desired length of the traces 206′ is reached. Specifically, these traces 206′ which are generally coupled to pin outs on the leading edges of the chip 202 are able to suffer from reflection losses due to the short length. As the result, the use of the non-linear paths that double back on themselves provide the benefit of reducing the loss of signal integrity due to signal reflection. In some embodiments, the chip 202 comprises an application specific integrated circuit (ASIC) for communicating with the optical interface modules. Alternatively, the chip 202 is able to comprise other types of chips such as general central processing units as are well known in the art. In some embodiments, the chip 202 has a square perimeter. Alternatively, the chip 202 is able to have a rectangular or other shaped perimeter. In some embodiments, the optical interface modules 204 each comprise one or more optical cable connectors and/or one or more optical interface cards for providing communication/connection functions between the chip 202 and other components (e.g. optical cables, ToR switch). Alternatively, the optical interface modules 204 are able to comprise more or less components as are well known in the art.

In some embodiments, the chip 202 comprises a hotspot H as shown in FIG. 2B wherein the heat produced by the chip 202 is most concentrated at the hotspot H. In some embodiments, the hotspot H is located at the ternary content-addressable memory (TCAMs) within the chip 202 and/or the location of other memory within the chip. As shown in FIG. 2B, the chip 202 is oriented with respect to the substrate 208 and/or the optical modules 204 such that the side or sides of the chip 202 closest to the hotspot H are at least partially facing toward the optical modules 204 and/or the edge of the substrate 208 upon which the optical modules 204 are located. In particular, the chip 202 is oriented such that the hotspot H is on a leading edge of the chip 202 with respect to the optical modules 204 and/or the edge of the substrate 208 upon which the optical modules 204 are located. As a result, the hotspot H is able to receive cooling airflow 99 (which generally flows from an airflow source, e.g. fan, on the other side of the optical modules 204 toward the chip 202) before the airflow 99 has been heated by other parts of the chip 202. Thus, the hotspot H of the chip 202 is more efficiently cooled thereby saving cooling energy and cost. It is noted that although as shown in FIG. 2B the chip 202 is rotated at 45 degrees with respect to the optical modules 204 and/or the edge of the substrate 208 upon which the optical modules 204 are located, all other angles are contemplated (including parallel) wherein the chip 202 is still able to be oriented such that the hotspot H proximate a leading edge of the chip 202 with respect to the airflow 99. It should also be noted that as shown in FIG. 2B some of the traces 206 as shown in FIG. 2A have been omitted for the sake of clarity.

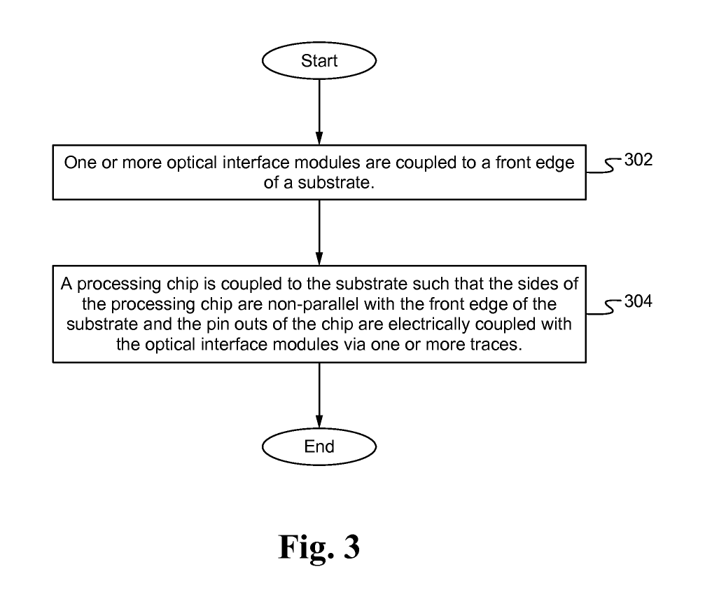

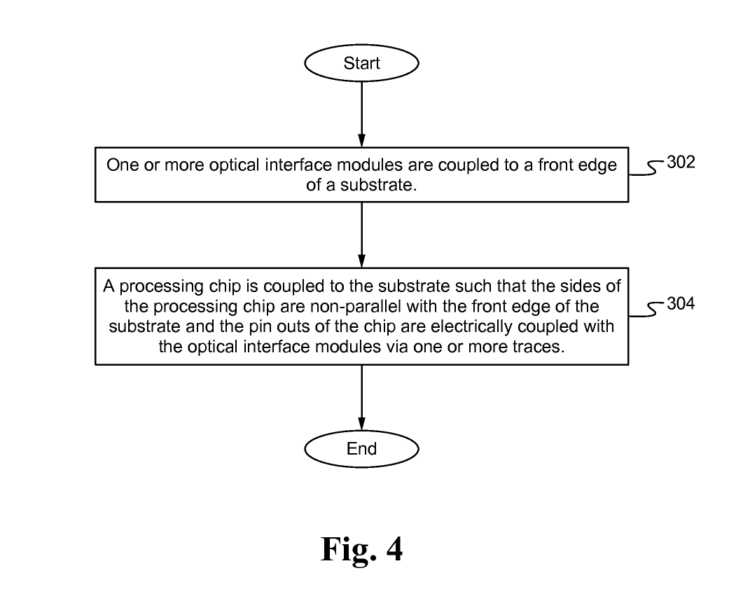

FIG. 3 illustrates a method of manufacturing an information processing device 108 for use in an information processing system 100 according to some embodiments. As shown in FIG. 3, one or more optical interface modules 204 are coupled to a front edge of a substrate 208 at the step 302. A processing chip 202 is coupled to the substrate 208 such that the sides of the processing chip 202 are non-parallel with the front edge of the substrate 208 and the pin outs of the chip 202 are electrically coupled with the optical interface modules 204 via one or more traces 206 at the step 304. In some embodiments, coupling the processing chip 202 to the substrate 208 comprises orienting the chip 202 such that the edge or edges of the chip 202 nearest a hotspot H are facing toward the front edge and/or the interface modules 204 (or a line that intersects the center of two or more of the modules 204). In some embodiments, the chip 202 is coupled such that the sides of the processing chip 202 are angled 45 degrees with respect to the front edge. Alternatively, the sides of the chip 202 are able to form other non-parallel angles with the front edge and/or the interface modules 204 (or a line that intersects the center of two or more of the modules 204). In some embodiments, the information processing device 108 is then electrically and/or physically coupled to a support structure 102. In some embodiments, air is then blown the front edge of the substrate 208 of the device 108 to a back edge of the substrate 208 that is opposite the front edge with a cooling element of the support structure 102. As a result, the method provides the advantages of reducing trace 206 length and thereby increasing signal strength, and increasing cooling efficiency by prioritizing the cooling of the hotspot H and reducing the heat transmission between the chip 202 and the modules 204.

The information processing system, device and method described herein has numerous advantages. Specifically, as described above, they provide the advantage of reducing the length and thereby the signal integrity loss produced by the traces which couple the pin outs of the chip to the optical modules. Further, they provide the benefit of limiting the cross heating between the chip and the optical modules due to the distancing portions of the chip from the modules. Moreover, they provide the advantage of efficiently cooling the chip hotspot H by positioning the hotspot H to receive cooler airflow. Thus, the information processing system, device and method has many advantages.

The present invention has been described in terms of specific embodiments incorporating details to facilitate the understanding of the principles of construction and operation of the invention. Such reference herein to specific embodiments and details thereof is not intended to limit the scope of the claims appended hereto. It will be apparent to those skilled in the art that modifications may be made in the embodiment chosen for illustration without departing from the spirit and scope of the invention.

1. An information processing system, comprising:
a support structure having an electronic interface; and
a plurality of blade boards each configured to detachably couple to the electronic interface, wherein each of the blade boards comprise:
a printed circuit board having a front board edge;
one or more optical interface modules positioned on the front edge of the circuit board and each having perimeter sides; and
a processing chip coupled to the circuit board and having a plurality of pin outs that are each electrically coupled to at least one of the optical interface modules via one or more traces on the circuit board;
wherein the sides of the processing chip are non-parallel with the perimeter sides of at least one of the optical interface modules and a direction of an airflow path of air from a cooling element.

2. The system of claim 1, wherein the sides of the processing chip are angled 45 degrees with respect to the front board edge.

3. The system of claim 2 wherein the perimeter of the processing chip comprises four corners and four sides in between the corners.

4. The system of claim 1, wherein the processing chip comprises ternary content-addressable memory located along one of the two sides closest to the optical interface modules.

5. The system of claim 1, wherein the sides of the processing chip are angled with respect to the front board edge such that the length of the traces between the pinouts and the optical interface modules is minimized.

6. The system of claim 2, wherein the support structure comprises the cooling element that forces air to move from the front board edge of the printed circuit board of each of the blade boards to a back board edge of the printed circuit board that is opposite the front board edge.

7. A blade board for use in an information processing system, the blade board comprising:
a printed circuit board having a front board edge;
one or more optical interface modules positioned on the front edge of the circuit board and each having perimeter sides; and
a processing chip coupled to the circuit board and having a plurality of pin outs that are each electrically coupled to at least one of the optical interface modules via one or more traces on the circuit board, wherein the sides of the processing chip are non-parallel with the perimeter sides of at least one of the optical interface modules and a direction of an airflow path of air from a cooling element.

8. The blade board of claim 7, wherein the sides of the processing chip are angled 45 degrees with respect to the front board edge.

9. The blade board of claim 8 wherein the perimeter of the processing chip comprises four corners and four sides in between the corners.

10. The blade board of claim 7, wherein the processing chip comprises ternary content-addressable memory located along one of the two sides closest to the optical interface modules.

11. The blade board of claim 7, wherein the sides of the processing chip are angled with respect to the front board edge such that the length of the traces between the pinouts and the optical interface modules is minimized.

12. A method of providing a blade board for use in an information processing system, the method comprising:
providing a blade board having a printed circuit board including a front board edge and one or more optical interface modules positioned on the front edge of the circuit board and each having perimeter sides; and
coupling a processing chip to the printed circuit board such that the sides of the processing chip are non-parallel with the perimeter sides of at least one of the optical interface modules and a direction of an airflow path of air from a cooling element, wherein the processing chip comprises a plurality of pin outs that are each electrically coupled to at least one of the optical interface modules via one or more traces on the circuit board.

13. The method of claim 12, wherein the sides of the processing chip are angled 45 degrees with respect to the front board edge.

14. The method of claim 13, wherein the perimeter of the processing chip comprises four corners and four sides in between the corners.

15. The method of claim 12, wherein the processing chip comprises ternary content-addressable memory located along one of the two sides closest to the optical interface modules.

16. The method of claim 12, wherein the sides of the processing chip are angled with respect to the front board edge such that the length of the traces between the pinouts and the optical interface modules is minimized.

17. The method of claim 12, further comprising detachably electrically coupling the blade board to an electronic interface of a support structure.

18. The method of claim 17, further comprising moving air from the front board edge of the printed circuit board of the blade board to a back board edge of the printed circuit board that is opposite the front board edge with the cooling element of the support structure.
